(19) United States
(12) Patent Application Publication
(10) Pub. No.: US 2025/0364291 A1
(43) Pub. Date: Nov. 27, 2025

(54) CARRIER STORAGE DEVICE, CARRIER STORAGE SYSTEM AND METHOD FOR TRANSPORTING CARRIER

(71) Applicant: Samsung Electronics Co., Ltd., Suwon-si (KR)

(72) Inventors: Hochan LEE, Suwon-si (KR); Dong-Hyuk LEE, Suwon-si (KR)

(21) Appl. No.: 18/950,407

(22) Filed: Nov. 18, 2024

(30) Foreign Application Priority Data
May 21, 2024 (KR) 10-2024-0066022

(51) Int. Cl. H01L 21/677

(52) U.S. Cl. CPC H01L 21/67736; H01L 21/67718; H01L 21/6773; H01L 21/67733

(57) ABSTRACT

A carrier storage device, including first ports disposed in a first region having a ring shape that is located in a vertical plane, wherein each of the first ports is configured to accommodate a corresponding carrier therein, a first rotating carriage coupled to each of the first ports and configured to rotatably move the first ports, second ports disposed in a second region having a ring shape that is located in the vertical plane, the second region being disposed in a space formed by the ring shape of the first region, wherein each of the second ports is configured to accommodate a corresponding carrier, and a second rotating carriage coupled to each of the second ports and configured to rotatably move the second ports, wherein a first opening is provided between two adjacent first ports, wherein the opening is configured to receive a transport container.

### CROSS-REFERENCE TO RELATED APPLICATION

This application claims priority to Korean Patent Application No. 10-2024-0066022, filed in the Korean Intellectual Property Office on May 21, 2024, the entire contents of which are hereby incorporated by reference.

### BACKGROUND

### Field

The present disclosure relates to a carrier storage device, a carrier storage system, and a method for transporting a carrier.

### Description of Related Art

In general, semiconductor devices can be manufactured by repeating a series of manufacturing processes on substrates such as silicon wafers, etc. For example, these manufacturing processes may be performed in a semiconductor manufacturing apparatus that handles and transports a plurality of wafers.

In this case, wafers may be provided to the manufacturing apparatus or returned from the manufacturing apparatus using a carrier loaded with the wafer, such as a Front Opening Unified Pod (FOUP), a Shipping Box (FOSB), etc. This carrier may generally be transported by an Overhead Hoist Transport (OHT) installed on a ceiling surface.

Meanwhile, during a manufacturing process, depending on needs of the semiconductor manufacturing apparatus, it may be necessary to transfer or load the carrier onto a storage device, or to store it in the storage device for inventory management. Accordingly, there is a need for an efficient logistics system for storing and transferring the carriers.

### SUMMARY

In order to solve one or more problems (e.g., the problems described above and/or other problems not explicitly described herein), the present disclosure provides a carrier storage device with increased carrier loading and unloading efficiency.

The present disclosure also provides a carrier storage system with increased loading and unloading efficiency.

The present disclosure also provides a method for transporting a carrier with increased loading and unloading efficiency.

According to some embodiments, at least one of a plurality of first ports and a plurality of second ports can be rotatably moved to load or unload a carrier to or from the one port, so that the carrier loading and unloading efficiency can be increased. Accordingly, efficiency of a carrier logistics system can be increased.

According to some embodiments of the present disclosure, a carrier storage device includes a plurality of first ports disposed in a first region having a ring shape that is located in a vertical plane, wherein each of the plurality of first ports is configured to accommodate a corresponding carrier therein; a first rotating carriage coupled to each of the plurality of first ports and configured to rotatably move the plurality of first ports; a plurality of second ports disposed in a second region having a ring shape that is located in the vertical plane, the second region being disposed in a space formed by the ring shape of the first region, wherein each of the plurality of second ports is configured to accommodate a corresponding carrier; and a second rotating carriage coupled to each of the plurality of second ports and configured to rotatably move the plurality of second ports, wherein a first opening is provided between two adjacent first ports of the plurality of first ports, wherein the opening is configured to receive a transport container.

According to some embodiments of the present disclosure, a carrier storage system includes a first transport rail extending in a horizontal direction; a first transport container configured to move along the first transport rail and to transport a carrier; a plurality of first ports disposed in a first region having a ring shape in a vertical plane, wherein each of the plurality of first ports is configured to accommodate a corresponding carrier therein; a first rotating carriage coupled to each of the plurality of first ports and configured to rotatably move the plurality of first ports; a plurality of second ports disposed in a second region having a ring shape, the second region being disposed in a central portion of the ring shape of the first region, wherein each of the plurality of second ports is configured to accommodate a corresponding carrier; and a second rotating carriage coupled to each of the plurality of second ports and configured to rotatably move the plurality of second ports, wherein an opening is provided between two adjacent first ports of the plurality of first ports, wherein the opening is configured to receive the first transport container.

According to some embodiments of the present disclosure, a method for transporting a carrier includes moving a transport container to a position above a carrier storage device; identifying whether a target port is a first port disposed in a first region of the carrier storage device or a second port disposed in a second region of the carrier storage device, wherein the first region is a ring-shaped region in a vertical plane, and the second region is a ring-shaped region disposed in a central portion of the ring shape of the first region; based on the identifying, determining a rotation amount of a first rotating carriage coupled to the first port and a second rotating carriage coupled to the second port; based on the determining, aligning the target port with the transport container by rotating at least one of the first rotating carriage and the second rotating carriage; and by the transport container, unloading a carrier disposed on the target port or loading the carrier onto the target port.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram provided to explain a carrier storage apparatus and a semiconductor apparatus according to some embodiments of the present disclosure;

FIG. 2 is a diagram provided to explain a carrier storage system according to some embodiments of the present disclosure;

FIG. 3 is a perspective view provided to explain a carrier storage device according to some embodiments of the present disclosure;

FIG. 4 is a diagram provided to explain a carrier storage device according to some embodiments of the present disclosure;

FIGS. 5 and 6 are diagrams provided to explain an operation of the carrier storage device according to some embodiments of the present disclosure;

FIG. 7 is a diagram provided to explain an operation of the carrier storage device according to some embodiments of the present disclosure;

FIG. 8 is a diagram provided to explain the carrier storage device according to some embodiments of the present disclosure;

FIG. 9 is a diagram provided to explain the carrier storage system according to some embodiments of the present disclosure;

FIG. 10 is a diagram provided to explain the carrier storage device according to some embodiments of the present disclosure;

FIG. 11 is a diagram provided to explain the carrier storage device according to some embodiments of the present disclosure;

FIG. 12 is a flowchart provided to explain a method for transporting a carrier according to some embodiments of the present disclosure.

### DETAILED DESCRIPTION

Hereinafter, a carrier storage device, a carrier storage system, and a method for transporting a carrier according to some embodiments will be described in detail with reference to the drawings.

An item, layer, or portion of an item or layer described as “extending” or as extending “lengthwise” in a particular direction has a length in the particular direction and a width perpendicular to that direction, where the length is greater than the width.

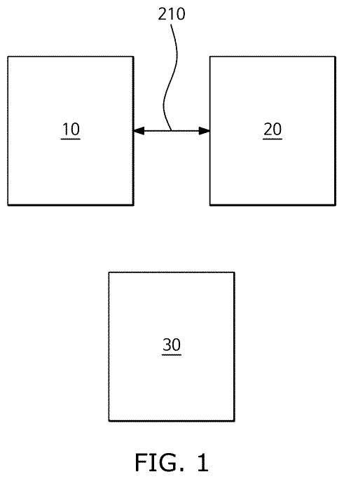

FIG. 1 is a diagram provided to explain a carrier storage apparatus and a semiconductor apparatus according to some embodiments of the present disclosure.

Referring to FIG. 1, a carrier storage apparatus 10 may provide a carrier to a semiconductor manufacturing apparatus 20 or may receive a carrier from the semiconductor manufacturing apparatus 20. The carrier may include a Front Opening Unified Pod (FOUP), a Shipping Box (FOSB), etc. to store a wafer used in a semiconductor manufacturing process.

The carrier storage apparatus 10 may be disposed on a semiconductor fab and store the carrier. For example, the carrier storage apparatus 10 may store the carrier transported by a transport unit 210 (e.g., a transport container). The transport unit 210 may include, for example, an overhead hoist transport (OHT). The transport unit 210 may transport the carrier between the carrier storage apparatus 10 and the semiconductor manufacturing apparatus 20. For example, the transport unit 210 may transport the carrier stored in the carrier storage apparatus 10 to the semiconductor manufacturing apparatus 20, or transport the carrier discharged from the semiconductor manufacturing apparatus 20 to the carrier storage apparatus 10.

The semiconductor manufacturing apparatus 20 may be an apparatus that performs various semiconductor processes. For example, deposition, cleaning, etching, and photolithography may be performed in the semiconductor manufacturing apparatus 20. According to some embodiments, the semiconductor manufacturing apparatus 20 may include an equipment front end module (EFEM) and a main module. The EFEM may be installed on one side of the main module. The EFEM may include a seating portion on which the carrier is seated. The transport unit 210 may load the carrier to the seating portion of the EFEM. The carrier loaded to the EFEM may be moved to the main module, where various manufacturing processes may be performed.

A controller 30 may control operations of the carrier storage apparatus 10, the semiconductor manufacturing apparatus 20, and the transport unit 210. The controller 30 may control the carrier storage apparatus 10 to unload the stored carrier from the carrier storage apparatus 10. The controller 30 may control the transport unit 210 to transport the carrier unloaded from the carrier storage apparatus 10 to the semiconductor manufacturing apparatus 20. The controller 30 may control the EFEM of the semiconductor manufacturing apparatus 20 to load the carrier transported from the transport unit 210.

Although not illustrated, the controller 30 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 30 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

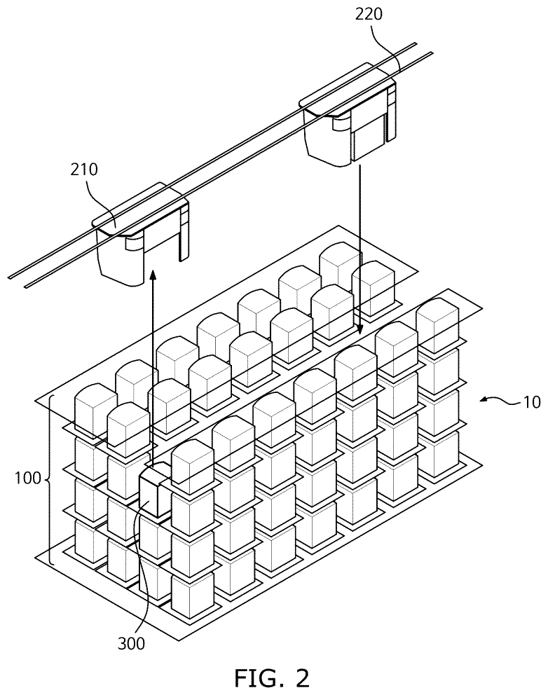

FIG. 2 is a diagram provided to explain a carrier storage system according to some embodiments of the present disclosure.

Referring to FIG. 2, the carrier storage system according to some embodiments may include the transport unit 210, a transport rail 220, the carrier storage apparatus 10, and a controller. The carrier storage apparatus 10 may include a plurality of carrier storage devices 100. The controller may control the carrier storage system for loading and unloading, and transporting the carrier.

The carrier storage system may include a bottom surface and a ceiling surface. The bottom surface may refer to a bottom surface of the semiconductor fab, and the ceiling surface may refer to a ceiling surface of the semiconductor fab. The transport rail 220 may be disposed on the ceiling surface of the semiconductor fab. The transport rail 220 may be a path along which the transport unit 210 is moved. The transport rail 220 may be disposed above the carrier storage apparatus 10. Although the transport rail 220 is illustrated in the form of a straight line, the transport rail 220 is not limited thereto. For example, the transport rail 220 may have a shape of a combination of a straight line and a curved line.

The transport unit 210 may travel along the transport rail 220. The transport unit 210 may grip a carrier 300 having a plurality of wafers accommodated therein and transport the same. The transport unit 210 may unload the stored carrier 300 from the carrier storage apparatus 10. The transport unit 210 may transport and load the carrier 300 onto the carrier storage apparatus 10.

The transport unit 210 may include a body, a driving module, a hoist, and a gripping module. The driving module may be coupled to the body to move the transport unit 210. One end of the hoist may be coupled to the body, and the other end of the hoist may be coupled to the gripping module. The gripping module may be raised and lowered by the hoist. The gripping module may grip or release the carrier 300.

In some embodiments, the transport unit 210 may further include a position sensor. The position sensor of the transport unit 210 may sense an alignment between the transport unit 210 and a port included in the carrier storage apparatus 10. For example, the transport unit 210 may be moved to above the carrier storage device 100, and the position sensor may sense whether there is a vertical alignment between the transport unit 210 and a target port.

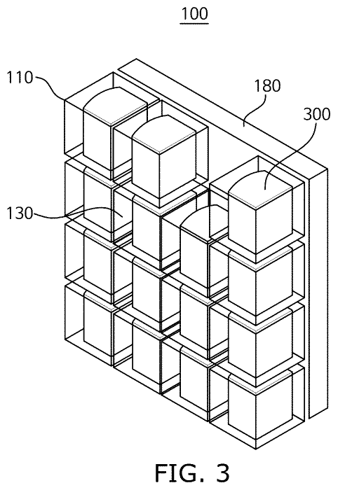

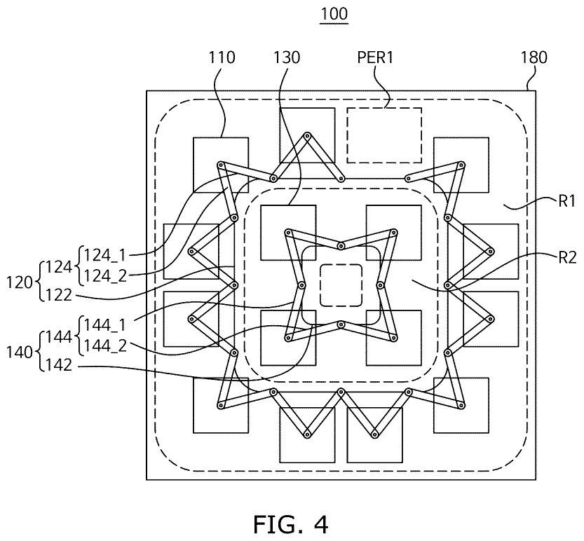

The carrier storage apparatus 10 may be disposed on the bottom surface (e.g., the floor) of the semiconductor fab. The carrier storage apparatus 10 may store a plurality of carriers 300. The carrier storage apparatus 10 may include a plurality of carrier storage devices 100. A plurality of carrier storage devices 100 may be aligned in one direction. Details of the carrier storage device 100 will be described below with reference to FIGS. 3 and 4.

FIG. 3 is a perspective view provided to explain a carrier storage device 100 according to some embodiments of the present disclosure. FIG. 4 is a diagram provided to explain a carrier storage device 100 according to some embodiments of the present disclosure.

Referring to FIGS. 3 and 4, the carrier storage device 100 according to some embodiments may include a plurality of first ports 110, a first rotation structure 120 (e.g., a first rotating carriage), a plurality of second ports 130, a second rotation structure 140 (e.g., a second rotating carriage), and a sealing member 180.

The plurality of first ports 110 and the first rotation structure 120 may be disposed on a first region R1. The first region R1 may have a shape of a ring defining a space therewithin. For example, the first region R1 may have a loop shape perpendicular to the ground. For example, the ring shape of the first region R1 may be located in a vertical plane. The ground may refer to the bottom surface of the semiconductor fab.

The first rotation structure 120 may include a first belt 122 and a first coupling member 124 (e.g., a first coupling arm). The first belt 122 may have a loop or ring shape. The first belt 122 may be rotatably moved by a first motor. For example, the first belt 122 may be rotatably moved in a clockwise or counterclockwise direction by the first motor.

The first coupling member 124 may couple the first belt 122 to each of the plurality of first ports 110. For example, one or more first ports 110 may be coupled to the first belt 122 by the first coupling member 124. Specifically, the first coupling member 124 may include a first sub-coupling member 124_1 (e.g., a first arm) and a second sub-coupling member 124_2 (e.g., a second arm). One end of the first sub-coupling member 124_1 and one end of the second sub-coupling member 124_2 may be coupled to the same position in the first port 110. The other end of the first sub-coupling member 124_1 and the other end of the second sub-coupling member 124_2 may be coupled to the first belt 122. The other end of the first sub-coupling member 124_1 and the other end of the second sub-coupling member 124_2 may be coupled to different positions on the first belt 122. Each of the first ports 110 may be coupled to a corresponding first sub-coupling member 124_1 and to a corresponding second sub-coupling member 124_2. For example, the first sub-coupling member 124_1 and the second sub-coupling member 124_2 may be attached to the corresponding first port 110 at the same position and may extend away from the first port 110 at different angles from each other such that the other ends of the first sub-coupling member 124_1 and the second sub-coupling member 124_2 are attached to the first belt 122 at different positions from each other.

The first sub-coupling member 124_1 and the second sub-coupling member 124_2 may have the same length as each other. The first sub-coupling member 124_1 and the second sub-coupling member 124_2 may form a predetermined angle with each other. The angles formed by the first sub-coupling member 124_1 and the second sub-coupling member 124_2 may not be regular. For example, an angle between the first sub-coupling member 124_1 and the second sub-coupling member 124_2 may be smaller at a corner of the first belt 122 than at a side of the first belt 122.

The plurality of first ports 110 may be disposed on the first region R1. Each of the plurality of first ports 110 may be coupled to the first rotation structure 120. As the first rotation structure 120 is rotatably moved, the plurality of first ports 110 may be moved together with the first rotation structure 120. For example, as the first rotation structure 120 is rotatably moved, the plurality of first ports 110 may be moved together in a loop that is located in a vertical plane.

The first port 110 may include a bottom, a side surface, and an opening. The carrier 300 may be seated on the bottom of the first port 110. The side surface of the first port 110 may be connected to the bottom and may surround the carrier 300. The opening of the first port 110 may be opposite to the bottom (e.g., the opening may be at the top of the first port 110). The carrier 300 may be loaded or unloaded through the opening of the first port 110. The first port 110 may have a six-sided cube or rectangular prism shape with an open upper surface. However, aspects are not limited to the above.

In some embodiments, a seating groove may be formed in the bottom of the first port 110. The seating groove of the bottom may include a shape corresponding to that of a lower surface of the carrier 300. The carrier 300 may be seated in the seating groove of the bottom and it may remain in place on the first port 110 while the first rotation structure 120 is moved.

When the first rotation structure 120 is moved, each of the plurality of first ports 110 may be aligned in the same direction. For example, when the first rotation structure 120 is rotatably moved, the bottom of the first port 110 may be maintained in a direction parallel to the ground. Specifically, the first sub-coupling member 124_1 and the second sub-coupling member 124_2 may be coupled to one axis that is coupled to the first port 110. The first port 110 may be configured such that, when the first rotation structure 120 is rotatably moved based on the axis, the bottom of the first port 110 may be maintained in a direction parallel to the ground, and the carrier 300 may be stably seated.

The plurality of second ports 130 and the second rotation structure 140 may be disposed on a second region R2. The second region R2 may have a shape of a ring defining a space therewithin. For example, the second region R2 may have a loop shape perpendicular to the ground. For example, the ring shape of the second region R1 may be located in a vertical plane. The second region R2 may be concentrically disposed in the space within the first region R1. The first region R1 may surround the second region R2.

The second rotation structure 140 may include a second belt 142 and a second coupling member 144 (e.g., a second coupling arm). The second belt 142 may have a loop or ring shape. The second belt 142 may be rotatably moved by a second motor. For example, the second belt 142 may be rotatably moved clockwise or counterclockwise by the second motor. The first motor to be connected to the first belt 122 and the second motor connected to the second belt 142 may be driven independently from each other. That is, the first rotation structure 120 and the second rotation structure 140 may be driven simultaneously or individually with a time difference.

The second coupling member 144 may couple the second belt 142 to each of the plurality of second ports 130. For example, one or more second ports 130 may be coupled to the second belt 142 by the second coupling member 144. Specifically, the second coupling member 144 may include a third sub-coupling member 144_1 (e.g., a third arm) and a fourth sub-coupling member 144_2 (e.g., a fourth arm). Descriptions of the third sub-coupling member 144_1 and the fourth sub-coupling member 144_2 may be similar to those of the first sub-coupling member 124_1 and the second sub-coupling member 124_2. Each of the second ports 130 may be coupled to a corresponding third sub-coupling member 144_1 and to a corresponding fourth sub-coupling member 144_2.

In some embodiments, the length of the first sub-coupling member 124_1 may be the same as the length of the third sub-coupling member 144_1. However, aspects are not limited thereto. For example, the length of the first sub-coupling member 124_1 may be different from the length of the third sub-coupling member 144_1.

The plurality of second ports 130 may be disposed on the second region R2. Each of the plurality of second ports 130 may be coupled to the second rotation structure 140. As the second rotation structure 140 is rotatably moved, the plurality of second ports 130 may be moved together with the second rotation structure 140. For example, as the second rotation structure 140 is rotatably moved, the plurality of second ports 130 may be moved together in a loop that is located in a vertical plane.

The second port 130 may include a bottom, a side surface, and an opening. The carrier 300 may be seated on the bottom of the second port 130. The side surface of the second port 130 may be connected to the bottom and may surround the carrier 300. The opening of the second port 130 may be opposite to the bottom (e.g., the opening may be at the top of the second port 130). The carrier 300 may be loaded or unloaded through the opening of the second port 130. The second port 130 may have a six-sided cube or rectangular prism shape with an open upper surface. However, aspects are not limited to the above.

In some embodiments, a seating groove may be formed in the bottom of the second port 130. The seating groove of the bottom may include a shape corresponding to a lower surface of the carrier 300. The carrier 300 may be seated in the seating groove of the bottom and it may remain in place on the second port 130 while the second rotation structure 140 is moved.

When the second rotation structure 140 is moved, each of the plurality of second ports 130 may be aligned in the same direction. For example, when the second rotation structure 140 is rotatably moved, the bottom of the second port 130 may be maintained in a direction parallel to the ground. Specifically, the third sub-coupling member 144_1 and the fourth sub-coupling member 144_2 may be coupled to one axis that is coupled to the second port 130. The second port 130 may be configured such that, when the second rotation structure 140 is rotatably moved based on the axis, the bottom of the second port 130 may be maintained in a direction parallel to the ground, and the carrier 300 may be stably seated.

A first port entrance region PER1 may be disposed on the first region R1. The first port entrance region PER1 may be disposed between any two ports (e.g., between two adjacent ports) of the plurality of first ports 110. The first port entrance region PER1 may be a region where no first port 110 is disposed. The first port entrance region PER1 may be a passage or opening through which the transport unit is received. A width of the first port entrance region PER1 may be equal to or greater than that of the transport unit. The width of the first port entrance region PER1 may be equal to or greater than that of the first port 110.

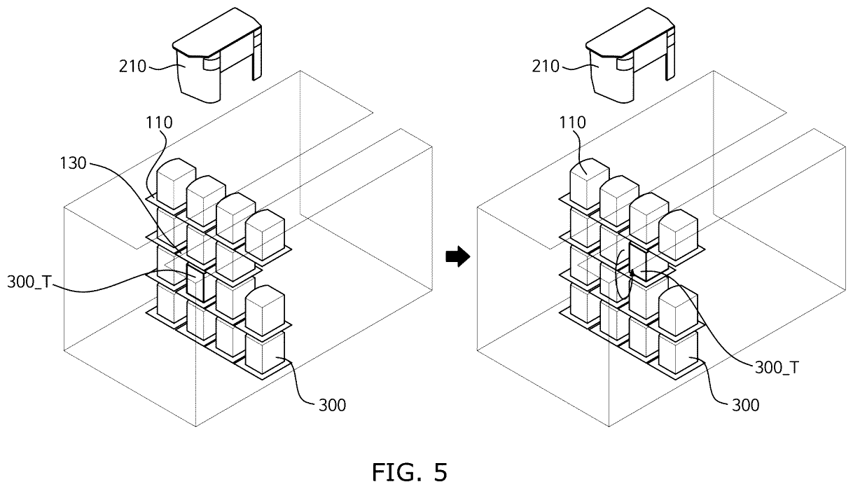

The transport unit may transfer or load the carrier 300 onto the first port 110 and the second port 130. For example, if the first port 110 and the transport unit are vertically aligned, the transport unit may transfer or load the carrier 300 onto the first port 110. As another example, the transport unit may pass through the first port entrance region PER1 and transfer or load the carrier 300 onto the second port 130 positioned underneath the first port entrance region PER1. Operations of the transport unit and the carrier storage device 100 will be described in detail with reference to FIGS. 5 to 7.

The sealing member 180 may be disposed on rear surfaces of the plurality of first ports 110 and the plurality of second ports 130 (see, e.g., FIG. 3). The rear surfaces of the plurality of first ports 110 and the plurality of second ports 130 may refer to surfaces to which the first coupling member 124 and the second coupling member 144 are coupled. The sealing member 180 may surround the first rotation structure 120 and the second rotation structure 140. The sealing member 180 may prevent diffusion of particles generated from the first rotation structure 120 and the second rotation structure 140.

FIGS. 5 and 6 are diagrams provided to explain an operation of the carrier storage device according to some embodiments of the present disclosure. For convenience of description, the side surface of the first port 110 of the carrier storage device, the side surface of the second port 130, the first rotation structure, the second rotation structure, the sealing member, etc. are omitted. An operation of unloading a target carrier 300_T disposed on the second port 130 will now be described.

Referring to FIG. 5, the carriers 300 may be stored on the plurality of first ports 110 and the plurality of second ports 130 of the carrier storage device. The transport unit 210 may be moved to above the carrier storage device. The controller may identify the target carrier 300_T. The target carrier 300_T may be the carrier 300 intended to be unloaded by the transport unit 210. In FIG. 5, the target carrier 300_T may be the carrier seated on the second port 130, of the plurality of second ports 130, that is disposed at a lower left side.

The controller may rotate the plurality of second ports 130 such that the target carrier 300_T is vertically aligned with the transport unit 210. The controller may rotatably move the plurality of second ports 130 counterclockwise (or clockwise) using the second rotation structure. Accordingly, the target carrier 300_T may be vertically aligned with the transport unit 210.

Referring to FIG. 6, the controller may rotatably move the plurality of first ports 110 so that the first port entrance region PER1 and the transport unit 210 are vertically aligned. The controller may rotatably move the plurality of first ports 110 counterclockwise (or clockwise) using the first rotation structure. For example, the plurality of first ports 110 may be rotatably moved counterclockwise, so that the first port entrance region PER1 may be vertically aligned with the transport unit 210.

The hoist of the transport unit 210 may vertically descend, and the gripping module of the transport unit 210 may grip the target carrier 300_T. Then the hoist of the transport unit 210 may ascend while gripping the target carrier 300_T, and the transport unit 210 may transport the target carrier 300_T.

Although the operation of unloading the target carrier 300_T from the port is described above, a similar process may be performed in the operation of unloading the carrier from a semiconductor manufacturing apparatus, etc. to a specific port of the carrier storage device, and redundant description will be omitted.

In some embodiments, the transport unit 210 may further include a position sensor. The position sensor of the transport unit 210 may sense whether the position of at least one of the first ports 110 and the second ports 130 as a target is aligned. For example, the position sensor of the transport unit 210 may sense whether it is aligned with the second port 130 on which the target carrier 300_T is seated. The controller may control the operation of the transport unit 210 based on a sensing value of the position sensor of the transport unit 210.

Referring to FIGS. 5 and 6, it is illustrated that the transport unit 210 is moved to a position above the carrier storage device, the plurality of second ports 130 are rotatably moved, and the plurality of first ports 110 are rotatably moved, but the aspects are not limited thereto. The movement of the transport unit 210, the rotatable movement of the plurality of first ports 110, and the rotatable movement of the plurality of second ports 130 may be performed simultaneously, individually with a time difference, or in different orders.

The carriers may be sequentially loaded onto the carrier storage device. Depending on the order of the semiconductor manufacturing process, it may be required to unload the previously loaded carriers. For a conventional stocker type carrier storage device in which carriers are stacked horizontally and vertically, since the carriers are unloaded in the reverse order the carriers are loaded, it is possible to unload the target carrier only after unloading all the carriers that have been loaded after the target carrier.

According to some embodiments of the present disclosure, the carrier storage device is capable of rotating the plurality of first ports 110 and the plurality of second ports 130 to unload the target carrier 300_T or load the carrier 300 on a specific port. It is possible to load and unload the target carrier 300_T regardless of the order in which the carriers 300 are loaded and unloaded. Accordingly, the carrier loading and unloading efficiency can be increased, and efficiency of the carrier logistics system can be increased.

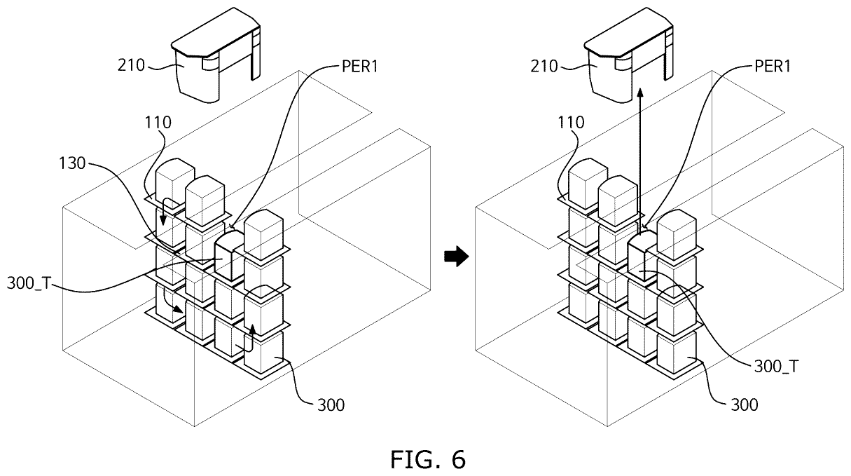

FIG. 7 is a diagram provided to explain an operation of the carrier storage device according to some embodiments of the present disclosure.

Referring to FIG. 7, the carriers 300 may be stored on the plurality of first ports 110 and the plurality of second ports 130 of the carrier storage device, respectively. The plurality of carriers 300 may include an error carrier 300_E and the target carrier 300_T. The error carrier 300_E may be the carrier 300 that was not input to the semiconductor manufacturing process and has to be unloaded. The target carrier 300_T may be the carrier 300 intended to be unloaded by the transport unit 210.

The controller may rotate the plurality of first ports 110 such that the target carrier 300_T is vertically aligned with the transport unit 210. For example, the controller may rotatably move the plurality of first ports 110 counterclockwise (or clockwise) using the first rotation structure. Accordingly, the target carrier 300_T may be vertically aligned with the transport unit 210. In the example of FIG. 7, the error carrier 300_E may be moved by one space counterclockwise.

The hoist of the transport unit 210 may vertically descend, and the gripping module of the transport unit 210 may grip the target carrier 300_T. Then the hoist of the transport unit 210 may ascend while gripping the target carrier 300_T, and the transport unit 210 may transport the target carrier 300_T.

If there is an error carrier in the carrier storage system, the error carrier may interfere with logistics of the carrier. For example, in order to unload the target carrier in a conventional stocker type carrier storage device, the target carrier can be unloaded only after the error carrier is unloaded. The carrier storage device according to some embodiments may unload the target carrier 300_T without having to remove the error carrier 300_E, by rotating the plurality of first ports 110 and the plurality of second ports 130. Accordingly, efficiency of carrier logistics can be increased.

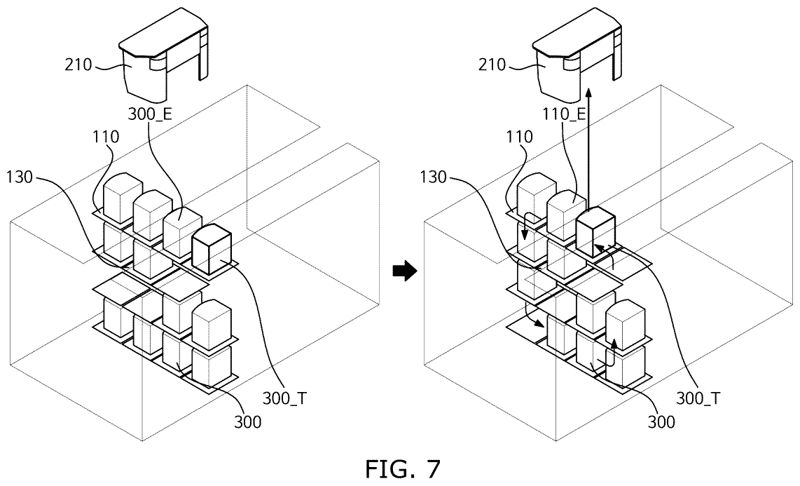

FIG. 8 is a diagram provided to explain the carrier storage device according to some embodiments of the present disclosure. For convenience of description, different configurations from those described in FIGS. 3 and 4 will be mainly described. Referring to FIG. 8, a carrier storage device 100B according to some embodiments may include the plurality of first ports 110, the first rotation structure 120, the plurality of second ports 130, the second rotation structure 140, a third port 150, and the sealing member 180.

The plurality of first ports 110 may be disposed on the first region R1. The plurality of second ports 130 may be disposed on the second region R2. The third port 150 may be disposed in a third region R3 positioned within the space formed by the ring shape of the second region R2.

The plurality of first ports 110 and the first rotation structure 120 may be disposed on the first region R1. The first region R1 may have a shape of a ring defining a space therewithin. For example, the first region R1 may have a loop or ring shape perpendicular to the ground (e.g., located in a vertical plane). The ground may refer to the bottom surface of the semiconductor fab. Description of the plurality of first ports 110 may be similar to those described above with reference to FIGS. 3 and 4.

The plurality of second ports 130 and the second rotation structure 140 may be disposed on the second region R2. The second region R2 may have a shape of a ring defining a space therewithin. For example, the second region R2 may have a loop or ring shape perpendicular to the ground (e.g., located in a vertical plane). The second region R2 may be disposed in the space formed by the ring shape of the first region R1. The first region R1 may surround the second region R2.

The plurality of second ports 130 may be disposed on the second region R2. Each of the plurality of second ports 130 may be coupled to the second rotation structure 140. As the second rotation structure 140 is rotatably moved, the plurality of second ports 130 may be moved together with the second rotation structure 140.

The third port 150 may be disposed on the third region R3. The third region R3 may have a rectangular shape perpendicular to the ground (e.g., located in a vertical plane). The third region R3 may be disposed in the space formed by the ring shape of the second region R2. Although one third port 150 is illustrated, aspects are not limited thereto. For example, the third region R3 may have a loop or ring shape perpendicular to the ground, and there may be a plurality of third ports 150. In addition, each of the third ports 150 may be coupled to a third rotation structure (not shown).

A first port entrance region PER1 may be disposed on the first region R1. The first port entrance region PER1 may be disposed between any two ports (e.g., between two adjacent first ports) of the plurality of first ports 110. The first port entrance region PERI may be a region where there is no first port 110 disposed therein. The first port entrance region PER1 may be a passage through which a transport unit is received. A width of the first port entrance region PER1 may be equal to or greater than that of the transport unit. The width of the first port entrance region PER1 may be equal to or greater than that of the first port 110.

A second port entrance region PER2 (e.g., a second opening) may be disposed on the second region R2. The second port entrance region PER2 may be disposed between any two ports (e.g., between two adjacent second ports) of the plurality of second ports 130. The second port entrance region PER2 may be a region where there is no second port 130 disposed therein. The second port entrance region PER2 may be a passage through which the transport unit is received. A width of the second port entrance region PER2 may be equal to or greater than that of the transport unit. The width of the second port entrance region PER2 may be equal to or greater than that of the second port 130.

In some embodiments, as the first rotation structure 120 and the second rotation structure 140 are rotatably moved, the first port entrance region PER1 and the second port entrance region PER2 may be aligned. As shown, the first port entrance region PER 1 and the second port entrance region PER2 may be vertically aligned with each other. The transport unit may pass the first port entrance region PER1 and the second port entrance region PER2 and load the carrier onto the third port 150 or unload the stored carrier from the third port 150.

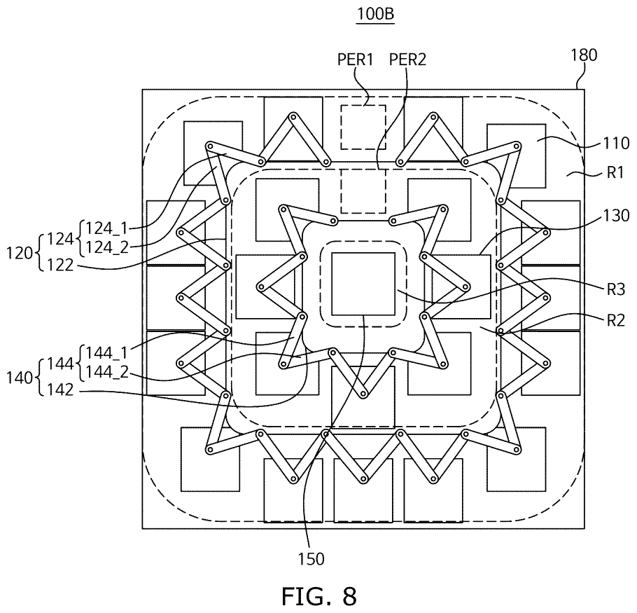

FIG. 9 is a diagram provided to explain the carrier storage system according to some embodiments of the present disclosure. For convenience of description, different configurations from those described in FIG. 2 will be mainly described.

Referring to FIG. 9, the carrier storage system according to some embodiments may include a first transport unit 210, a first transport rail 220, a second transport unit 230 (e.g., a second transport container), a second transport rail 240, the carrier storage apparatus 10, and a controller. The carrier storage apparatus 10 may include a plurality of carrier storage devices 100. The controller may control the carrier storage system for loading and unloading, and transporting the carrier.

Each of the first transport rail 220 and the second transport rail 240 may be disposed on the ceiling surface of the semiconductor fab. Each of the first transport rail 220 and the second transport rail 240 may be disposed above the carrier storage apparatus 10. Each of the first transport rail 220 and the second transport rail 240 is illustrated in a straight line, but aspects are not limited thereto. For example, each of the first transport rail 220 and the second transport rail 240 may have a shape of a combination of a straight line and a curved line.

The first transport rail 220 and the second transport rail 240 may be disposed at a space apart from each other. The first transport rail 220 may be disposed to vertically overlap a third row in the carrier storage apparatus 10. The second transport rail 240 may be disposed to vertically overlap a first row in the carrier storage apparatus 10. For example, as shown in FIG. 9, the third row of the carrier storage apparatus 10 may be located in a vertical plane that is perpendicular to a vertical plane of the carrier storage device 100 and may include a third column of the carrier storage device 100. For example, as shown in FIG. 9, the first row of the carrier storage apparatus 10 may be located in a vertical plane that is perpendicular to the vertical plane of the carrier storage device 100 and may include a first column of the carrier storage device 100.

The first transport unit 210 may travel along the first transport rail 220. The second transport unit 230 may travel along the second transport rail 240. The first transport unit 210 may load or unload the carrier disposed in the third row in the carrier storage apparatus 10. The second transport unit 230 may load or unload the carrier disposed in the first row in the carrier storage apparatus 10.

The first transport unit 210 and the second transport unit 230 may be driven independently. By using the first transport unit 210 and the second transport unit 230, carrier logistics time can be shortened, and carrier logistics efficiency can be improved. In the example of FIG. 9, it is described that two transport units are driven, but aspects are not limited thereto, and a larger number of transport units may transfer or load the carriers to the carrier storage apparatus 10.

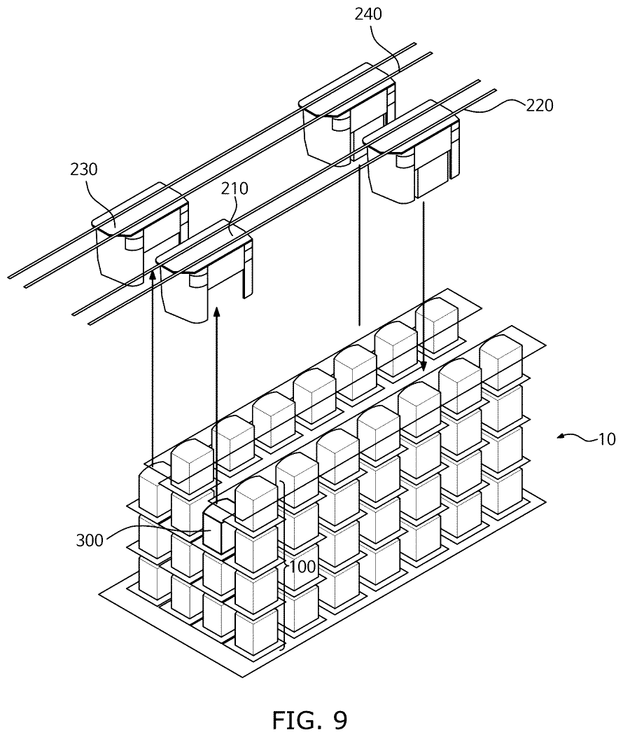

FIG. 10 is a diagram provided to explain the carrier storage device according to some embodiments of the present disclosure. For convenience of description, different configurations from those described in FIGS. 3 and 4 will be mainly described.

Referring to FIG. 10, a carrier storage device 100C according to some embodiments may include the plurality of first ports 110, the first rotation structure, the plurality of second ports 130, and the second rotation structure.

The plurality of first ports 110 may be disposed in a first region, and the plurality of second ports 130 may be disposed in a second region. The first region and the second region of FIG. 10 may have a similar shape to the shape of the first region R1 and the second region R2 of FIG. 4, except that the first region and the second region of FIG. 10 are further extended in the height direction. The plurality of first ports 110 may surround the plurality of second ports 130. The plurality of second ports 130 may refer to, for example, 12 ports disposed in the center, and the plurality of first ports 110 may refer to, for example, 19 ports disposed around the second ports 130.

Depending on the arrangement of a semiconductor manufacturing apparatus in the semiconductor fab, the height of the semiconductor fab may vary. It is therefore desirable to secure more storage space for the carrier storage device. To this end, the carrier storage device may be manufactured to a height that does not interfere with the transport unit (e.g., OHT). In the carrier storage device 100C according to some embodiments, the carrier storage space can be increased by expanding the number of ports in the height direction.

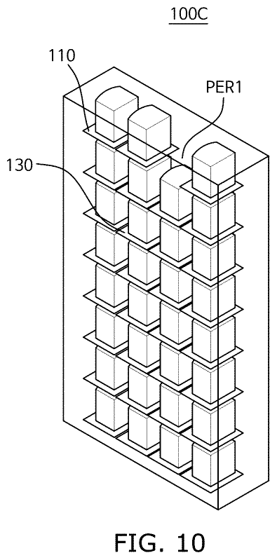

FIG. 11 is a diagram provided to explain the carrier storage device according to some embodiments of the present disclosure. For convenience of description, different configurations from those described in FIGS. 3 and 4 will be mainly described.

Referring to FIG. 11, a carrier storage device 100D according to some embodiments may include the plurality of first ports 110, the first rotation structure, the plurality of second ports 130, and the second rotation structure.

The plurality of first ports 110 may be disposed in a first region, and the plurality of second ports 130 may be arranged in a second region. The first region and the second region of FIG. 11 may have a similar shape to the shape of the first region R1 and the second region R2 of FIG. 4, except that the first region and the second region of FIG. 11 are further extended in the horizontal direction. The plurality of first ports 110 may surround the plurality of second ports 130. The plurality of second ports 130 may refer to, for example, 10 ports disposed in the center, and the plurality of first ports 110 may refer to, for example, 16 ports disposed around the second ports 130.

A first sub-port entrance region PER1_1 (e.g., a first opening) may be disposed between two adjacent first ports of the plurality of first ports 110, and a second sub-port entrance region PER1_2 (e.g., a second opening) may be disposed between two other adjacent first ports of the plurality of first ports 110. Each of the first sub-port entrance region PER1_1 and the second sub-port entrance region PER1_2 may be a region where no first port 110 is disposed. Each of the first sub-port entrance region PER1_1 and the second sub-port entrance region PER1_2 may be a passage through which the transport unit is received. The width of each of the first sub-port entrance region PER1_1 and the second sub-port entrance region PER1_2 may be equal to or greater than that of the transport unit.

In some embodiments, a plurality of transport units may be disposed on the carrier storage device 100D. In this case, the carrier may be loaded or unloaded independently of the plurality of transport units, through each of the first sub-port entrance region PER1_1 and the second sub-port entrance region PER1_2.

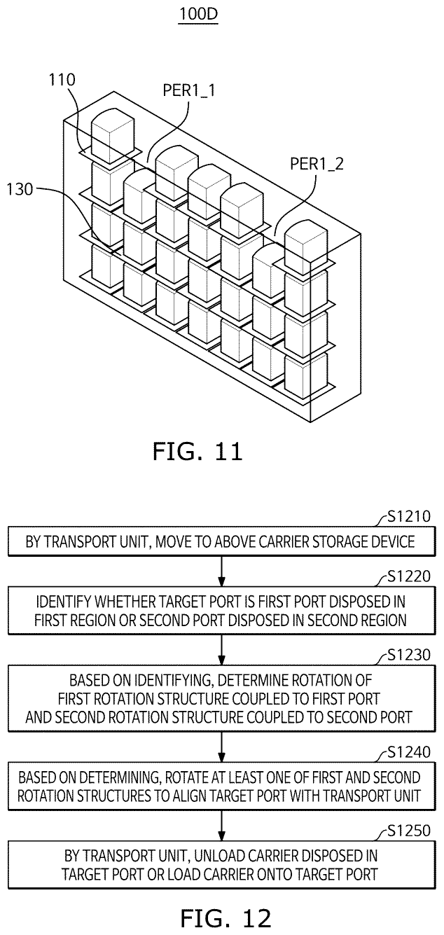

FIG. 12 is a flowchart provided to explain a method for transporting a carrier according to some embodiments of the present disclosure.

Referring to FIG. 12, a method for transporting a carrier according to some embodiments may be initiated as the transport unit is moved to a position above the carrier storage device, at S1210. The controller may control the transport unit to move to the position above the carrier storage device.

The controller may identify whether a target port is the first port disposed in the first region or the second port disposed in the second region, at S1220. The target port may be a port to which the carrier is loaded or from which the carrier is unloaded.

Based on the identification, the controller may determine a rotation of the first rotation structure coupled to the first port and the second rotation structure coupled to the second port, at S1230.

Based on the determination, the controller may rotate at least one of the first rotation structure and the second rotation structure to vertically align the target port with the transport unit, at S1240. For example, the controller may rotate the first rotation structure based on the target port being the first port so as to vertically align the target port with the transport unit. As another example, based on the target port being the second port, the controller may rotate the first rotation structure to vertically align the port entrance region with the transport unit, and rotate the second rotation structure to vertically align the target port with the port entrance region.

The controller may control the transport unit to unload the carrier disposed on the target port, or load the carrier onto the target port, at S1250.

Although certain aspects of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A carrier storage device, comprising:
a plurality of first ports disposed in a first region having a ring shape that is located in a vertical plane, wherein each of the plurality of first ports is configured to accommodate a corresponding carrier therein;
a first rotating carriage coupled to each of the plurality of first ports and configured to rotatably move the plurality of first ports;
a plurality of second ports disposed in a second region having a ring shape that is located in the vertical plane, the second region being disposed in a space formed by the ring shape of the first region, wherein each of the plurality of second ports is configured to accommodate a corresponding carrier; and
a second rotating carriage coupled to each of the plurality of second ports and configured to rotatably move the plurality of second ports, wherein
a first opening is provided between two adjacent first ports of the plurality of first ports, wherein the opening is configured to receive a transport container.

2. The carrier storage device of claim 1, wherein the transport container is configured to unload the carrier from a port from among the plurality of first ports and the plurality of second ports, or to load the carrier into the port.

3. The carrier storage device of claim 1, wherein each of the plurality of first ports includes a bottom on which the corresponding carrier is seated, a side surface connected to the bottom and surrounding the corresponding carrier, and an opening opposite to the bottom.

4. The carrier storage device of claim 1, wherein the first rotating carriage includes a belt that is configured to be rotatably moved, and a coupling arm that couples the belt to each of the plurality of first ports.

5. The carrier storage device of claim 4, wherein
the coupling arm includes a first arm and a second arm,
one end of the first arm and one end of the second arm are coupled to the same position in a first port from among the plurality of first ports, and
the other end of the first arm and the other end of the second arm are respectively coupled to different positions on the belt.

6. The carrier storage device of claim 1, wherein a width of the opening is equal to or greater than a width of the transport container.

7. The carrier storage device of claim 1, wherein
the first rotating carriage is configured to be driven by a first motor,
the second rotating carriage is configured to be driven by a second motor, and
the first motor and the second motor are driven independently from each other.

8. The carrier storage device of claim 1, further comprising a sealing member surrounding the first rotating carriage and the second rotating carriage.

9. The carrier storage device of claim 1, wherein a second opening is provided between two adjacent second ports of the plurality of second ports.

10. The carrier storage device of claim 9, further comprising one or more third ports disposed in a central portion of the ring shape of the second region.

11. A carrier storage system, comprising:
a first transport rail extending in a horizontal direction;
a first transport container configured to move along the first transport rail and to transport a carrier;
a plurality of first ports disposed in a first region having a ring shape in a vertical plane, wherein each of the plurality of first ports is configured to accommodate a corresponding carrier therein;
a first rotating carriage coupled to each of the plurality of first ports and configured to rotatably move the plurality of first ports;
a plurality of second ports disposed in a second region having a ring shape, the second region being disposed in a central portion of the ring shape of the first region, wherein each of the plurality of second ports is configured to accommodate a corresponding carrier; and
a second rotating carriage coupled to each of the plurality of second ports and configured to rotatably move the plurality of second ports, wherein
an opening is provided between two adjacent first ports of the plurality of first ports, wherein the opening is configured to receive the first transport container.

12. The carrier storage system of claim 11, wherein the first transport container is configured to move in the vertical direction, and to unload the carrier from a port from among the plurality of first ports and the plurality of second ports, or to load the carrier into the port.

13. The carrier storage system of claim 11, wherein the first transport container is configured to pass through the opening, and to unload the carrier from second port of the plurality of second ports or to load the carrier into the second port.

14. The carrier storage system of claim 11, further comprising:
a second transport rail disposed on one side of the first transport rail; and
a second transport container configured to move along the second transport rail and to transport the carrier.

15. The carrier storage system of claim 11, wherein
the first rotating carriage includes a first belt that is configured to rotatably move, and a first coupling arm coupling the first belt to each of the plurality of first ports, and
the second rotating carriage includes a second belt that is configured to rotatably move, and a second coupling arm coupling the second belt to each of the plurality of second ports.

16. The carrier storage system of claim 11, wherein a second opening is provided between two other adjacent first ports of the plurality of first ports.

17. A method for transporting a carrier, comprising:
moving a transport container to a position above a carrier storage device;
identifying whether a target port is a first port disposed in a first region of the carrier storage device or a second port disposed in a second region of the carrier storage device, wherein the first region is a ring-shaped region in a vertical plane, and the second region is a ring-shaped region disposed in a central portion of the ring shape of the first region;
based on the identifying, determining a rotation amount of a first rotating carriage coupled to the first port and a second rotating carriage coupled to the second port;
based on the determining, aligning the target port with the transport container by rotating at least one of the first rotating carriage and the second rotating carriage; and
by the transport container, unloading a carrier disposed on the target port or loading the carrier onto the target port.

18. The carrier storage system of claim 17, wherein the aligning includes, based on the target port being the first port, rotating the first rotating carriage to align the target port with the transport container.

19. The carrier storage system of claim 17, wherein, the aligning the target port includes, based on the target port being the second port:
rotating the first rotating carriage to align an opening provided in the first region with the transport container; and
rotating the second rotating carriage to align the target port with the opening.

20. The carrier storage system of claim 17, wherein the first rotating carriage and the second rotating carriage are driven independently from each other.
